(19) United States
(12) Patent Application Publication
(10) Pub. No.: US 2026/0011548 A1
(43) Pub. Date: Jan. 8, 2026

(54) REDUCED UNDERLAYER OXIDATION DURING GAP FILL

(71) Applicant: Applied Materials, Inc., Santa Clara, CA (US)

(72) Inventors: Sukrant Dhawan, Santa Clara, CA (US); Bhaskar Soman, San Jose, CA (US); Susmit Singha Roy, Campbell, CA (US); Supriya Ghosh, San Jose, CA (US); Akhil Singhal, Portland, OR (US)

(73) Assignee: Applied Materials, Inc., Santa Clara, CA (US)

(21) Appl. No.: 18/761,660

(22) Filed: Jul. 2, 2024

(51) Int. Cl. H01L 21/02; C23C 16/34; C23C 16/40; C23C 16/455

(52) U.S. Cl. CPC H01L 21/0228; C23C 16/345; C23C 16/401; C23C 16/45529; C23C 16/45536; H01L 21/02164; H01L 21/0217; H01L 21/0223

(57) ABSTRACT

Exemplary processing methods may include providing one or more deposition precursors to a processing region of a semiconductor processing chamber. A substrate may be disposed within the processing region. A layer of a first silicon-containing material defining one or more features may be disposed on the substrate. The methods may include contacting the substrate with the one or more deposition precursors. The contacting may deposit a liner material on the first silicon-containing material. The methods may include performing an atomic layer deposition (ALD) process. The ALD process may deposit a silicon-and-oxygen-containing material in the one or more features.

### TECHNICAL FIELD

The present technology relates to semiconductor processing. More specifically, the present technology relates to methods of gap filling of silicon-containing materials with reduced underlayer oxidation.

### BACKGROUND

Integrated circuits are made possible by processes which produce intricately patterned material layers on substrate surfaces. Producing patterned material on a substrate requires controlled methods of formation and removal of exposed material. As device sizes continue to shrink, material formation may affect subsequent operations. For example, in gap filling operations a material may be formed or deposited to fill a trench or other feature formed on a semiconductor substrate. As features may be characterized by higher aspect ratios and reduced critical dimensions, these filling operations may be challenged. For example, as the deposition may occur at the top and along sidewalls of the feature, continued deposition may pinch off the feature including between sidewalls within the feature, and may produce voids within the feature. This can impact device performance and subsequent processing operations.

Thus, there is a need for improved systems and methods that can be used to produce high quality devices and structures. These and other needs are addressed by the present technology.

### SUMMARY

Exemplary processing methods may include providing one or more deposition precursors to a processing region of a semiconductor processing chamber. A substrate may be disposed within the processing region. A layer of a first silicon-containing material defining one or more features may be disposed on the substrate. The methods may include contacting the substrate with the one or more deposition precursors. The contacting may deposit a liner material on the first silicon-containing material. The methods may include performing an atomic layer deposition (ALD) process. The ALD process may deposit a silicon-and-oxygen-containing material in the one or more features.

In some embodiments, the deposition precursors may be or include a silicon-containing precursor, a carbon-containing precursor, or a nitrogen-containing precursor. The deposition precursors may be or include diatomic nitrogen (N₂) or ammonia (NH₃). The first silicon-containing material may be or include a silicon-and-germanium-containing material. The layer of the first silicon-containing material may be disposed on the substrate in alternation with a layer of a second silicon-containing material. The liner material may be characterized by a thickness less than or about 10 nm. The liner material may be or include a silicon-and-nitrogen-containing material. Contacting the substrate with the one or more deposition precursors to deposit the liner material may include performing a liner material ALD process. Performing the ALD process may reduce an upper surface thickness of the layer of the first silicon-containing material by less than or about 5 nm. Performing the ALD process may convert the liner material to silicon-and-oxygen-containing material. The ALD process may be a gap-fill operation.

Some embodiments of the present technology may encompass semiconductor processing methods. The methods may include performing a first atomic layer deposition (ALD) process on a substrate disposed within a processing region of a semiconductor processing chamber. A layer of a silicon-containing material defining one or more features may be disposed on the substrate. The first ALD process may deposit a silicon-and-nitrogen-containing material on the silicon-containing material. The methods may include halting the first ALD process. The methods may include performing a second ALD process on the substrate. The second ALD process may deposit a silicon-and-oxygen-containing material in the one or more features.

In some embodiments, the silicon-and-nitrogen-containing material may be conformal. The first ALD process may include sequentially exposing the substrate to a silicon-containing precursor and a nitrogen-containing precursor. The nitrogen-containing precursor may be or include ammonia (NH₃). Subsequent the second ALD process, the silicon-and-nitrogen-containing material may be converted to silicon-and-oxygen-containing material. The silicon-and-nitrogen-containing material may reduce underlayer oxidation of the layer of the silicon-containing material.

Some embodiments of the present technology may encompass semiconductor processing methods. The methods may include performing a first atomic layer deposition (ALD) process on a substrate disposed within a processing region of a semiconductor processing chamber. Alternating layers of a silicon-containing material and a silicon-and-germanium-containing material defining one or more features may be disposed on the substrate. The first ALD process may conformally deposits a silicon-and-nitrogen-containing liner material on the alternating layers of the silicon-containing material and the silicon-and-germanium-containing material. The methods may include halting the first ALD process after the silicon-and-nitrogen-containing liner material is formed to a thickness of greater than or about 2 nm. The methods may include performing a second ALD process on the substrate. The second ALD process deposits a silicon-and-oxygen-containing material in the one or more features.

In some embodiments, deposition of the silicon-and-nitrogen-containing liner material may be self-limiting. Subsequent the second ALD process, the silicon-and-nitrogen-containing liner material may be converted to silicon-and-oxygen-containing material.

Such technology may provide numerous benefits over conventional systems and techniques. For example, by depositing a liner material, oxidation of underlying material may be avoided, which may reduce or prevent rounding of the underlying material. Additionally, by performing an ALD or plasma-enhanced ALD (PEALD) process to deposit silicon-containing material, such as silicon-and-oxygen-containing material, may convert the liner material such that no unwanted constituents from the liner material are present in the gap fill material. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

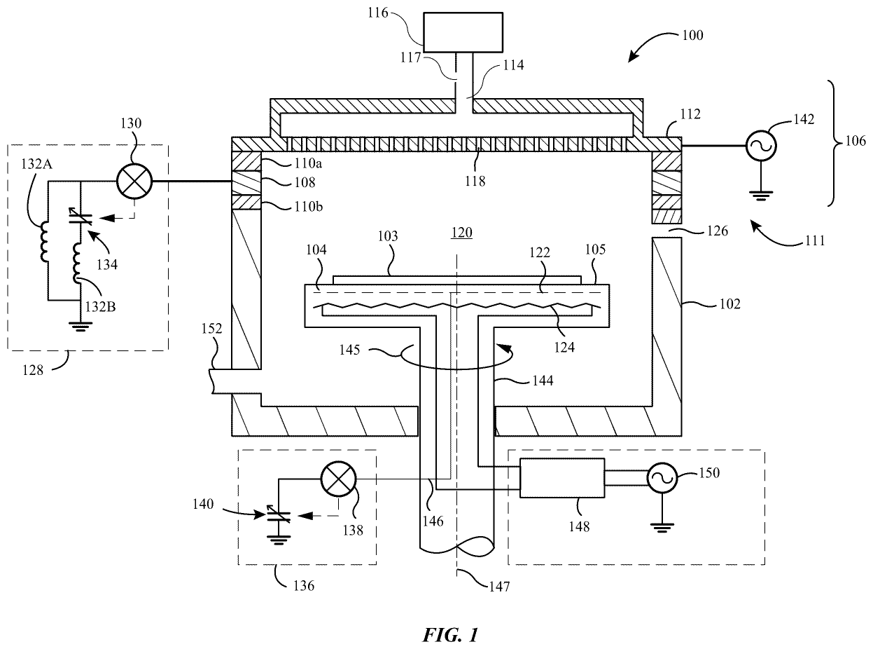

FIG. 1 shows a schematic cross-sectional view of an exemplary processing chamber according to some embodiments of the present technology.

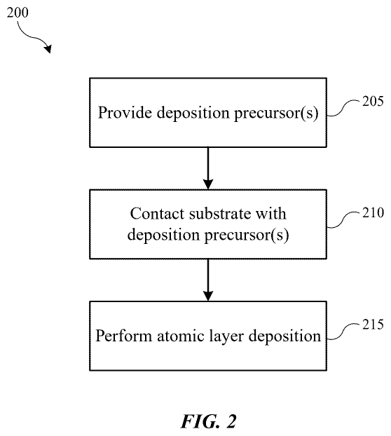

FIG. 2 shows exemplary operations in a processing method according to some embodiments of the present technology.

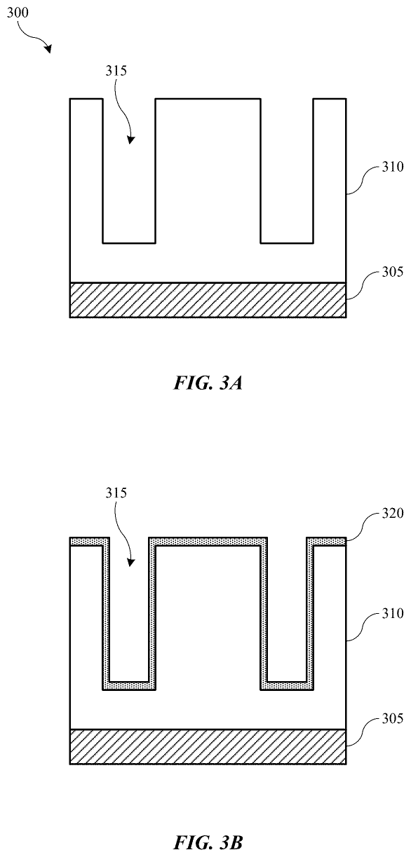

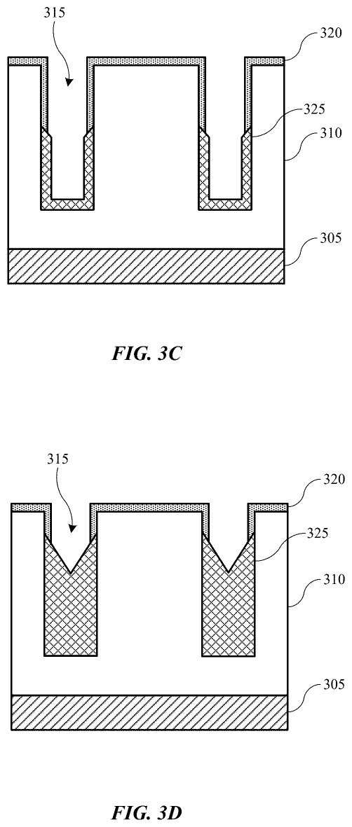

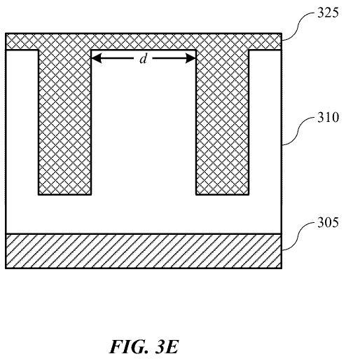

FIGS. 3A-3E show schematic cross-sectional views of a substrate during a processing according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Silicon-containing materials may be used in semiconductor device manufacturing for a number of structures and processes. Some examples include using silicon-containing materials as a sacrificial material. For example, the silicon-and-oxygen-containing material may be used as, but is not limited to, a dummy gate material or as a trench fill material. In other examples, silicon-containing materials may be used in deep trench isolation (DTI) structures. In gap filling operations, some processing may utilize plasma-enhanced deposition under process conditions to increase the directionality of the deposition, which may allow the deposited material to better fill features on the substrate.

As feature sizes continue to shrink, distance between features being gap filled, sometimes referred to as pillar width, also may decrease. Depending on the material defining the features, upper portions of the material may be prone to reaction with the gap fill precursors. For example, in a silicon-and-oxygen-containing gap fill, an upper portion of the material defining the features may be prone to reaction with an oxygen-containing, resulting in oxidation of the material. Conventional technologies have attempted to address this issue by depositing a barrier material to prevent reaction between the material defining the features and one or more of the precursors used for the gap fill. However, these conventional technologies typically deposit an excessive amount of barrier material at an upper portion of the material defining the features. This excessive deposition may negatively impact the subsequent gap fill process, possibly resulting in formation of a scam or a void in the gap fill material. Additionally, some portion of the barrier material may undesirably remain present in the final structure.

The present technology may overcome these limitations by depositing a liner material over the material defining the one or more features. The liner material may be deposited using an atomic layer deposition (ALD) or a plasma-enhanced ALD (PEALD) process. By depositing using an ALD or PEALD process, the deposition of the liner material may be self-limiting. As such, the thickness of the liner material may be controlled by the number of cycles of the ALD or PEALD process. As such, the present technology may avoid depositing an excessive amount of liner material at an upper portion of the material defining the features. Further, by depositing a controlled thickness of the liner material, the subsequent gap filling process may convert the liner material to material being deposited in the features. Thus, the present technology reduces or prevents formation of reaction between the between the material defining the features and one or more of the precursors used for the gap fill while simultaneously reducing or preventing formation of a scam or a void in the gap fill material.

After describing general aspects of a chamber according to some embodiments of the present technology in which gap filling operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

FIG. 1 shows a cross-sectional view of an exemplary processing chamber 100 according to some embodiments of the present technology. The figure may illustrate an overview of a system incorporating one or more aspects of the present technology, and/or which may perform one or more deposition or other processing operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112, also referred to as a faceplate, and from the chamber body 102. The gas distributor 112 may define apertures 118 for distributing process precursors into the processing volume 120.

The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

Processing chamber 100 may be utilized in some embodiments of the present technology for processing methods that may include gap filling materials for semiconductor structures. It is to be understood that the chamber described is not to be considered limiting, and any chamber that may be configured to perform operations as described may be similarly used.

FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3E, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures on a substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

As illustrated in FIG. 3A, a substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. Substrate 305 may be any number of materials used in semiconductor processing. The substrate material may be or include silicon, germanium, dielectric materials including silicon oxide or silicon nitride, metal materials, or any number of combinations of these materials, which may be the substrate 305, or materials formed in structure 300. The substrate 305 may include a material 310 in which one or more features 315 may be formed. The material 310 may be a layer of a silicon-containing material. In embodiments, the silicon-containing material of material 310 may be a silicon-and-germanium-containing material. While not illustrated in FIG. 3A, it is contemplated that material 310 may be a layer of a silicon-and-germanium-containing material in a stack of alternating layers of silicon-containing material (e.g., silicon) and silicon-and-germanium-containing material (e.g., silicon germanium). More specifically, material 310 may be an uppermost layer of silicon-and-germanium-containing material disposed on the substrate 305 in alternation with a layer of a second silicon-containing material, such as silicon. The substrate 305 may include multiple pairs of silicon-and-germanium-containing material and silicon-containing material in alternation. Features 315 formed in material 310 may be characterized by any shape or configuration according to the present technology. In some embodiments, the features 315 may be or include a trench structure or aperture formed within the material 310 and/or substrate 305.

Although the features 315 may be characterized by any shapes or sizes, in some embodiments the features 315 may be characterized by higher aspect ratios, or a ratio of a depth of the feature to a width across the feature. For example, in some embodiments features 315 may be characterized by aspect ratios greater than or about 1:1, and may be characterized by aspect ratios greater than or about 5:1, greater than or about 10:1, greater than or about 15:1, greater than or about 20:1, greater than or about 30:1, greater than or about 40:1, greater than or about 50:1, greater than or about 60:1, greater than or about 70:1, greater than or about 80:1, greater than or about 90:1, or greater. Additionally, the features may be characterized by narrow widths or diameters across the feature including between two sidewalls, such as a dimension of less than or about 100 nm, and may be characterized by a width across the feature of less than or about 90 nm, less than or about 80 nm, less than or about 70 nm, less than or about 60 nm, less than or about 50 nm, less than or about 40 nm, less than or about 30 nm, or less. Further, the features may be characterized by a depth of greater than or about 100 nm, and may be characterized by a depth of greater than or about 250 nm, greater than or about 500 nm, greater than or about 750 nm, greater than or about 1 μm, greater than or about 1.5 μm, greater than or about 2 μm, greater than or about 2.5 μm, greater than or about 3 μm, greater than or about 3.5 μm, greater than or about 4 μm, greater than or about 4.5 μm, greater than or about 5 μm, or more.

Additionally, while FIG. 3A illustrates features 315 extending partially into material 310, it is contemplated that the features 315 may extend entirely through material 310. Further, features 315 may extend through additional materials under material 310 and/or may even extend into substrate 305.

Method 200 may include gap filling materials for semiconductor structures. However, to reduce or prevent the oxidation of one or more materials underlying the material being deposited within the feature, which may occur in conventional ALD and/or PEALD processes, method 200 may include depositing a liner material on materials underlying the material being deposited within the feature to reduce or prevent undesirable oxidation. As such, method 200 may include providing one or more deposition precursors to the processing region at operation 205. At operation 210, method 200 may include contacting the substrate 305 with the one or more deposition precursors. As illustrated in FIG. 3B, the contacting may form a liner material 320 the substrate 305 that may at least partially line the feature 315. In embodiments, the liner material 320 may fully line the feature 315. As illustrated in FIG. 3B, the liner material 320 may be conformal. Depending on the deposition precursor(s) used, in embodiments, the liner material 320 may be a silicon-containing material, such as a silicon-and-nitrogen-containing material or a silicon-carbon-and-nitrogen-containing material. Subsequent to forming the liner material 320, method 200 may include performing an ALD or PEALD process at operation 220 as illustrated in FIG. 3C. The ALD or PEALD process may be a silicon-containing ALD or PEALD process to deposit silicon-containing material 325 in the features 315, such as in a gap fill process.

The one or more deposition precursors provided to the processing region at operation 205 may be or include precursors that may form a silicon-containing material, such as a silicon-and-nitrogen-containing material or a silicon-carbon-and-nitrogen-containing material. As such, the deposition precursors may include one or more of a silicon-containing precursor, a carbon-containing precursor, a nitrogen-containing precursor, or precursors including one or more of silicon, carbon, and/or nitrogen. Although any silicon-containing precursor may be used, in some embodiments, a silicon-containing precursor that may be provided during operation 205 may include, but is not limited to, silane (SiH₄), disilane (Si₂H₆), trisilane (Si₃H₈), tetrasilane (Si₄H₁₀), pentasilane (Si₅H₁₂), or other organosilanes including cyclohexasilanes, an aminosilane, silicon tetrafluoride (SiF₄), silicon tetrachloride (SiCl₄), dichlorosilane (SiH₂Cl₂), tetraethyl orthosilicate (TEOS), as well as any other silicon-containing materials that may be used or useful in semiconductor processing. Additionally, although any carbon-containing precursor may be used, in some embodiments, a carbon-containing precursor that may be provided during operation 205 may include, but is not limited to, carbon tetrafluoride (CF₄), tetrafluoroethylene (C₂F₄), octafluorocyclobutane (C₄F₈), hexafluorobutadiene (C₄F₆), fluoroform (or trifluoromethane) (CHF₃), difluoromethane (CH₂F₂), methyl fluoride (or fluoromethane) (CH₃F), or other hydrocarbons or fluorocarbons, carbon dioxide (CO₂), thionyl chloride (SO₂), carbon monoxide (CO), as well as any other carbon-containing materials that may be used or useful in semiconductor processing. Again, although any nitrogen-containing precursor may be used, in some embodiments, a nitrogen-containing precursor that may be provided during operation 205 may include, but is not limited to, diatomic nitrogen (N₂), nitrogen trifluoride (NF₃), ammonia (NH₃), nitrogen dioxide (NO₂), nitrous oxide (N₂O), as well as any other nitrogen-containing materials that may be used or useful in semiconductor processing. An exemplary nitrogen-containing precursor may be NH₃, which may result in a self-limiting deposition of liner material 320. NH₃ may also serve as an inhibitor to reduce or prevent deposition of silicon-containing material 325 at an upper portion of the feature 315. The poisoning may reduce or prevent pinching or closing at an upper portion of the feature 315, which may lead so a scam or void in the silicon-containing material 325. In some embodiments, to reduce or prevent oxidation of underlying materials, such as material 310, the one or more deposition precursors may be oxygen-free. As such, the processing region may be maintained oxygen-free while providing the one or more deposition precursor at operation 205, as well as contacting the substrate 305 with the one or more deposition precursors at operation 210. In embodiments, the one or more deposition precursors may be provided with one or more diluents or carrier gases such as an inert gas or other gas delivered with the one or more deposition precursors.

Some embodiments may include forming plasma effluents of the one or more deposition precursors. The power applied during deposition may be a lower power plasma, which may reduce dissociation and deposition rate. Accordingly, in some embodiments a plasma power source may deliver a plasma power to the faceplate, chamber, or substrate support of less than or about 5,000 W, and may deliver a power of less than or about 4,500 W, less than or about 4,000 W, less than or about 3,500 W, less than or about 3,000 W, less than or about 2,500 W, less than or about 2,000 W, less than or about 1,500 W, less than or about 1,000 W, less than or about 500 W, or less. However, to deposit a higher quality or denser liner material 320, the plasma power source may deliver a plasma power to the faceplate, chamber, or substrate support of greater than or about 250 W, and may deliver a power of greater than or about 500 W, greater than or about 750 W, greater than or about 1,000 W, greater than or about 1,250 W, greater than or about 1,500 W, greater than or about 2,000 W, greater than or about 2,500 W, greater than or about 3,000 W, or more.

In embodiments, depositing the liner material 320 may be an ALD or PEALD process. It is also contemplated that the liner material 320 may be deposited using any other thermal or plasma-enhanced deposition process. However, performing an ALD or PEALD process to deposit the liner material 320 may increase conformality of the liner material 320. The ALD or PEALD process may also contribute to the deposition of the silicon-and-nitrogen-containing liner material being self-limiting. The ALD or PEALD process to deposit the liner material 320 may include a layer by layer deposition of, for example, silicon-and-nitrogen-containing material. The ALD or PEALD process may include a first precursor dose, such as a silicon-containing precursor dose or a nitrogen-containing precursor dose. In PEALD processes, plasma effluents of the first precursor dose may be formed. The first precursor dose or, if formed, plasma effluents thereof may be adsorbed, such as through chemisorption, on the substrate 305 or material 310. A first purge may be performed to remove excess amounts of the first precursor dose, such as the first precursor that has not been absorbed on the substrate 305 or material 310.

After the first purge, the ALD or PEALD process may include a second precursor dose, such as a silicon-containing precursor dose or a nitrogen-containing precursor (the opposite of the first precursor dose). In PEALD processes, plasma effluents of the second precursor dose may be formed. The second precursor or, if formed, plasma effluents thereof may react with the first precursor dose adsorbed on the substrate 305 or material 310. The reaction between the first precursor dose and the second precursor dose may form the liner material 320. A second purge may be performed to remove excess amounts of the second precursor dose, such as the second precursor that has not reacted with the first precursor to form liner material 320. After the second purge, the first precursor dose, first purge, second precursor dose, and second purge, the operations may be repeated any number of times to continue forming liner material 320.

In embodiments, the liner material 320 may be deposited to a thickness of less than or about 10 nm. At increased thicknesses, such as thicknesses greater than 10 nm, the liner material 320 may not be converted to the gap fill material, such as silicon-containing material 325, during the subsequent ALD or PEALD process as discussed below. As such, the liner material 320 may be deposited to a thickness of less than or about 9 nm, less than or about 8 nm, less than or about 7 nm, less than or about 6 nm, less than about 5 nm, less than or about 4.8 nm, less than or about 4.6 nm, less than or about 4.4 nm, less than or about 4.2 nm, less than or about 4.0 nm, less than or about 3.8 nm, less than or about 3.6 nm, less than or about 3.5 nm, less than or about 3.4 nm, less than or about 3.3 nm, less than or about 3.2 nm, less than or about 3.1 nm, less than or about 3.0 nm, or less. At reduced thicknesses, however, the liner material 320 may not be sufficient to prevent an oxygen-containing precursor, which may be used during the subsequent ALD or PEALD process, from diffusing through the liner material and potentially oxidizing material 310. As such, the liner material 320 may be deposited to a thickness of greater than or about 1.0 nm, greater than or about 1.2 nm, greater than or about 1.4 nm, greater than or about 1.6 nm, greater than or about 1.8 nm, greater than or about 2.0 nm, greater than or about 2.1 nm, greater than or about 2.2 nm, greater than or about 2.3 nm, greater than or about 2.4 nm, greater than or about 2.5 nm, greater than or about 2.6 nm, greater than or about 2.7 nm, greater than or about 2.8 nm, greater than or about 2.9 nm, greater than or about 3.0 nm, or more.

After forming the liner material 320 for a period of time, method 200 may include halting a flow of the one or more deposition precursors. Halting the flow of the one or more deposition precursors may halt the deposition, such as the ALD or PEALD process. The period of time may be sufficient to form the liner material 320 to a desired thickness, such as any of the thicknesses previously discussed, to reduce or prevent the oxidation of material 310. By reducing or preventing the oxidation of material 310 at upper portions of the feature 315, the deposition of silicon-containing material 325 may proceed without compromising underlying material 320. Thus, the deposited liner material 320 may reduce or prevent oxidation, which may cause rounding at an upper surface of the material 320 defining the features 315.

As previously discussed, subsequent to forming the liner material 320, method 200 may include performing an ALD or PEALD process, such as a silicon-containing ALD or PEALD process, at operation 220. Similar to the ALD or PEALD process to deposit the liner material 320, the silicon-containing ALD or PEALD process may include a layer by layer deposition of silicon-containing material 325. The silicon-containing ALD or PEALD process may include a first precursor dose, such as a silicon-containing precursor dose or an oxygen-containing precursor dose. In PEALD processes, plasma effluents of the first precursor dose may be formed. The first precursor dose or, if formed, plasma effluents thereof may be adsorbed, such as through chemisorption, on the substrate 305 or material 310. A first purge may be performed to remove excess amounts of the first precursor dose, such as the first precursor that has not been absorbed on the substrate 305 or material 310.

After the first purge, the silicon-containing ALD or PEALD process may include a second precursor dose, such as a silicon-containing precursor dose or an oxygen-containing precursor (the opposite of the first precursor dose). In PEALD processes, plasma effluents of the second precursor dose may be formed. The second precursor or, if formed, plasma effluents thereof may react with the first precursor dose adsorbed on the substrate 305 or material 310. The reaction between the first precursor dose and the second precursor dose may form the silicon-containing material 325. A second purge may be performed to remove excess amounts of the second precursor dose, such as the second precursor that has not reacted with the first precursor to form silicon-containing material 325.

During the oxygen-containing precursor dose, whether the first precursor dose or second precursor does, the liner material 320 may be at least partially, if not fully, converted to a silicon-and-oxygen-containing material. The oxygen-containing precursor, or plasma effluents thereof, may react with the, for example, silicon-and-carbon-containing material of the liner material 310 to form volatiles that may be purged from the processing region. For example, the oxygen-containing precursor may react with silicon-and-carbon-containing material of the liner material 310 to form CO, CO₂, N₂O, NO₂, or other gaseous carbon-containing materials, nitrogen-containing materials, and/or oxygen-containing materials that may be pumped out of the processing region. The reduction or removal of the liner material 320 may advantageously allow the deposition of silicon-containing material to fill the features 315 without the presence of the liner material 320, such as carbon or nitrogen in the liner material 320, after the features 315 are filled. Thus, as illustrated in FIGS. 3C-3E, the silicon-containing ALD or PEALD process may fill the features 315 with silicon-containing material 325 without the liner material 320 intervening or being present between material 310 and the silicon-containing material 325. After the second purge, the first precursor dose, first purge, second precursor dose, and second purge, the operations may be repeated any number of times to continue forming silicon-containing material 325.

Although any silicon-containing precursor may be used, in some embodiments, the silicon-containing precursor(s) may be used during the silicon-containing ALD or PEALD process may include, but are not limited to, SiH₄, Si₂H₆, Si₃H₈, Si₄H₁₀, Si₅H₁₂, or other organosilanes including cyclohexasilanes, an aminosilane, SiF₄, SiCl₄, SiH₂Cl₂, TEOS, as well as any other silicon-containing materials that may be used or useful in semiconductor processing. Similarly, although any oxygen-containing precursor may be used, in some embodiments, the oxygen-containing precursor(s) may be used during the silicon-containing ALD or PEALD process may include, but are not limited to, diatomic oxygen (O₂), N₂O, hydrogen peroxide (H₂O₂), ozone (O₃), or other oxygen-containing materials that may be used or useful in semiconductor processing.

If plasma-enhanced, the power applied during the silicon-containing PEALD, a plasma power source may deliver a plasma power to the faceplate, chamber, or substrate support of greater than or about 100 W, and may deliver a power of greater than or about 250 W, greater than or about 500 W, greater than or about 1,000 W, greater than or about 1,500 W, greater than or about 2,000 W, greater than or about 2,500 W, greater than or about 3,000 W, greater than or about 3,500 W, greater than or about 4,000 W, greater than or about 4,500 W, greater than or about 5,000 W, greater than or about 5,500 W, greater than or about 6,000 W, greater than or about 7,000 W, greater than or about 8,000 W, or more. The plasma power may impact deposition rate, conformality, and/or quality of the deposited material. For example, higher plasma powers may deposit a higher quality material and/or may deposit material at an increased deposition rate, but may result in damage to other materials or structures on the substrate 305.

As previously discussed, after the second purge, the first precursor dose, first purge, second precursor dose, and second purge, the operations may be repeated any number of times to continue forming silicon-containing material 325. However, to maintain a bottom-up, zipper-like fashion of the gap fill with reduced scam or void formation, method 200 may include intermittently performing the deposition of liner material 310 of operations 205-210.

Due to the presence of the liner material 320, performing the ALD or PEALD process to deposit the silicon-containing material 325 may reduce (or oxidized) an upper surface thickness, such as thickness d shown in FIG. 3E, of the layer of the material 310, such as the silicon-containing material, by less than or about 5 nm. In embodiments, the presence of the liner material 320 may result in the upper surface thickness of the layer of the material 310 being reduced (or oxidized) by less than or about 4.8 nm, less than or about 4.6 nm, less than or about 4.4 nm, less than or about 4.2 nm, less than or about 4.0 nm, less than or about 3.8 nm, less than or about 3.6 nm, less than or about 3.4 nm, less than or about 3.2 nm, less than or about 3.0 nm, less than or about 2.8 nm, less than or about 2.6 nm, less than or about 2.4 nm, less than or about 2.2 nm, less than or about 2.0 nm, less than or about 1.9 nm, less than or about 1.8 nm, less than or about 1.7 nm, less than or about 1.6 nm, less than or about 1.5 nm, or less.

Temperature may impact operations of the present technology. For example, the method 200 may be performed at a temperature less than or about 600° C., and may be performed at a temperature less than or about less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., or less. Additionally, the method 200 may be performed at a temperature greater than or about 100° C., and may be performed at a temperature greater than or about 300° C., and may be performed at a temperature greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., or more. The temperature may be maintained in any of these ranges throughout the method 200, including during the poisoning and the deposition. However, it is also contemplated that the temperature may be adjusted between operations.

Pressure may also impact operations of the present technology. For example, the method 200 may be performed at a pressure less than or about 50 Torr, and may be performed at a pressure less than or about 40 Torr, less than or about 30 Torr, less than or about 20 Torr, less than or about 15 Torr, less than or about 10 Torr, less than or about 8 Torr, less than or about 6 Torr, less than or about 5 Torr, less than or about 4 Torr, less than or about 3 Torr, less than or about 2 Torr, less than or about 1 Torr, or less.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a first silicon-containing material” includes a plurality of such materials, and reference to “the deposition precursors” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing one or more deposition precursors to a processing region of a semiconductor processing chamber, wherein a substrate is disposed within the processing region, and wherein a layer of a first silicon-containing material defining one or more features is disposed on the substrate;
contacting the substrate with the one or more deposition precursors, wherein the contacting deposits a liner material on the first silicon-containing material;
performing an atomic layer deposition (ALD) process, wherein the ALD process deposits a silicon-and-oxygen-containing material in the one or more features.

2. The semiconductor processing method of claim 1, wherein the deposition precursors comprise a silicon-containing precursor, a carbon-containing precursor, or a nitrogen-containing precursor.

3. The semiconductor processing method of claim 1, wherein the deposition precursors comprise diatomic nitrogen (N₂) or ammonia (NH₃).

4. The semiconductor processing method of claim 1, wherein the first silicon-containing material comprises a silicon-and-germanium-containing material.

5. The semiconductor processing method of claim 1, wherein the layer of the first silicon-containing material is disposed on the substrate in alternation with a layer of a second silicon-containing material.

6. The semiconductor processing method of claim 1, wherein the liner material is characterized by a thickness less than or about 10 nm.

7. The semiconductor processing method of claim 1, wherein the liner material comprises a silicon-and-nitrogen-containing material.

8. The semiconductor processing method of claim 1, wherein contacting the substrate with the one or more deposition precursors to deposit the liner material comprises performing a liner material ALD process.

9. The semiconductor processing method of claim 1, wherein performing the ALD process reduces an upper surface thickness of the layer of the first silicon-containing material by less than or about 5 nm.

10. The semiconductor processing method of claim 1, wherein performing the ALD process converts the liner material to silicon-and-oxygen-containing material.

11. The semiconductor processing method of claim 1, wherein the ALD process comprises a gap-fill operation.

12. A semiconductor processing method comprising:
performing a first atomic layer deposition (ALD) process on a substrate disposed within a processing region of a semiconductor processing chamber, wherein a layer of a silicon-containing material defining one or more features is disposed on the substrate, and wherein the first ALD process deposits a silicon-and-nitrogen-containing material on the silicon-containing material;
halting the first ALD process;
performing a second ALD process on the substrate, wherein the second ALD process deposits a silicon-and-oxygen-containing material in the one or more features.

13. The semiconductor processing method of claim 12, wherein the silicon-and-nitrogen-containing material is conformal.

14. The semiconductor processing method of claim 12, wherein the first ALD process comprises sequentially exposing the substrate to a silicon-containing precursor and a nitrogen-containing precursor.

15. The semiconductor processing method of claim 14, wherein the nitrogen-containing precursor comprises ammonia (NH₃).

16. The semiconductor processing method of claim 12, wherein, subsequent the second ALD process, the silicon-and-nitrogen-containing material is converted to silicon-and-oxygen-containing material.

17. The semiconductor processing method of claim 12, wherein the silicon-and-nitrogen-containing material reduces underlayer oxidation of the layer of the silicon-containing material.

18. A semiconductor processing method comprising:
performing a first atomic layer deposition (ALD) process on a substrate disposed within a processing region of a semiconductor processing chamber, wherein alternating layers of a silicon-containing material and a silicon-and-germanium-containing material defining one or more features is disposed on the substrate, and wherein the first ALD process conformally deposits a silicon-and-nitrogen-containing liner material on the alternating layers of the silicon-containing material and the silicon-and-germanium-containing material;
halting the first ALD process after the silicon-and-nitrogen-containing liner material is formed to a thickness of greater than or about 2 nm;
performing a second ALD process on the substrate, wherein the second ALD process deposits a silicon-and-oxygen-containing material in the one or more features.

19. The semiconductor processing method of claim 18, wherein deposition of the silicon-and-nitrogen-containing liner material is self-limiting.

20. The semiconductor processing method of claim 18, wherein, subsequent the second ALD process, the silicon-and-nitrogen-containing liner material is converted to silicon-and-oxygen-containing material.
